(19) United States
(12) Patent Application Publication
(10) Pub. No.: US 2004/0002832 A1
(43) Pub. Date: Jan. 1, 2004

(54) Method and apparatus for boundary scan of serial interfaces

(76) Inventor: Patrick P. Chan, Rocklin, CA (US)

Correspondence Address: Jack I. J'maev, SUITE 110, 11800 CENTRAL AVE., CHINO, CA, 91710, US

(21) Appl. No.: 10/412,746

(22) Filed: Apr. 9, 2003

Related U.S. Application Data
(60) Provisional application No. 60/382,299, filed on May 20, 2002.

(51) Int. Cl. G06F 19/00; G01R 27/28; G01R 31/00; G01R 31/14

(52) U.S. Cl. 702/120

(57) ABSTRACT

Serial interfaces on integrated circuits are tested in near-real-time by boundary scan cells. Serial inputs are converted to logic states that are sampled concurrently by a test access port. Test access port data is serialized and driven in near-real-time outward from the integrated circuit.

### RELATED APPLICATIONS

This present application is related to a provisional application serial number 60/382,299 filed on May 20, 2002, entitled “Method and Apparatus for Boundary Scan of Serial Interfaces”, by Chain, currently pending, for which the priority date for this application is hereby claimed.

### FIELD OF THE INVENTION

This invention relates generally to integrated circuit support for board level testing.

### BACKGROUND OF THE INVENTION

Electronic systems are typically built from subassemblies. Each subassembly may comprise several circuit boards that are populated with active components and passive components. Passive components are electronic devices that typically require no operating power. They may, however, dissipate power. Resistors, capacitors, inductor and diodes may all be considered passive devices. Active devices typical use power to drive other parts of an electronic circuit. Transistor based amplifiers and integrated circuits are typically considered to be active elements on a circuit board.

One of the most difficult aspects of testing a fully assembled circuit board is that of identifying if an active component is operating properly. When an active device is mounted on a circuit board, it is difficult to determine if the circuit board is causing a problem or if it is the active device itself that is faulty. For instance, if an active device is attempting to drive a circuit board trace but the logic level on the circuit trace is not correct, it may be due to a short of the circuit trace to another trace or it may be the result of a faulty logic system buried deep in the active integrated circuit.

As integrated circuits became more complex, the need to support board level Is testability was addressed by an IEEE standard for boundary testing of an integrated circuit (IEEE 1149.1). Boundary level testing, according to modern industry trends, provides for a test access port (TAP). The TAP port allows external test apparatus to communicate over a serial interface with each input or output pin on an integrated circuit. Using the TAP interface, any given output pin integral to an integrated circuit may be driven to a particular state irrespective of the output of a functional logic element that would normally be reflected at that output pin. The TAP interface may also be used to retrieve the value perceived at an input pin. Using the serial interface, external test apparatus may read the state present at each input pin.

The TAP interface becomes useful when automated test equipment is used to identify board level faults. The TAP interface is generally used to drive the output pins of one integrated circuit in accordance with a test pattern. The TAP interface can then be used to retrieve the value perceived by an input pin on another integrated circuit. The test apparatus can then compare the perceived pattern from an input pin against the test pattern applied to the output pin to identify faults. In many cases, this technique may be used to identify the source of a fault.

TAP interface based testing has truly advanced the art of board level testing of electronic assemblies and systems. For all of its benefit, TAP interface based testing has been limited to low-rate application of test patterns. Real-time testing is simply not supported unless the system intrinsically operates at a low frequency. The TAP interface only provides for update and telemetry at a 1 MHz serial bit rate, some implementations operate at much higher frequencies.

Full-speed testing of circuit boards is extremely important when printed circuit traces need to carry high-speed data. As data transition frequency increases, even the impedance of traces on a circuit board may influence the performance of the completed assembly. This is especially true in electronic assemblies that are directed toward high-speed communications such as networking equipment.

Serial interfaces are especially susceptible to faults that can only be detected during full speed operation. Where serial interfaces are involved, the TAP interface is usually far to slow to be able to drive an output pin at a full-speed serial data rate. TAP interface update rates may never increase to the level necessary to support impedance sensitivity testing of assembled circuit boards.

### SUMMARY

The present invention comprises a method for driving an integrated circuit output pin with a serial bit stream. Accordingly, to support substantially real-time transmission of a serial bit stream from the output pin of an integrated circuit, one illustrative method of the present invention provides for receiving a plurality of logic states from a functional circuit element that may comprise the integrated circuit. Also, a plurality of logic states may be received from a test access port. When so commanded, the logic states from the test access port may be substituted for the logic states received from the functional circuit elements comprising the integrated circuit.

A serializer may be used to receive the logic states either from the functional circuit element or the substitute values received from the test access port. The serializer may then be clocked in order to create a bit stream representative of the logic state values. Hence, according to this illustrative method of the present invention, substitute values received from the test access port may be used as the basis of a bit stream pattern that may be emitted from the integrated circuit output pin in substantially real-time time.

According to one variation of the present method, the bit stream emitted by the serializer comprises a time-sequential plurality of logic levels. When driving the output pin, a first voltage level can be used to represent a logic level received from the shift register. This first voltage level may be adjusted to represent a second logic level. When a differential output is provided by an integrated circuit, a second voltage level may be used to represent the inverse of the logic level.

The present invention further comprises a method for monitoring the serial input that may be received by a serial input pin comprising an integrated circuit. When receiving a serial input stream, the stream may be first directed to a serial-to-parallel converter. In this example method, the output of the serial-to-parallel converter normally comprises a plurality of logic states. According to this variation of the inventive method, the logic states may be conveyed to an application specific functional circuit element comprising the integrated circuit. Further comprising this illustrative method, the logic states may be directed to a test access port when said test port is active.

One example variation of the present method provides that a stream of bits may be received by an integrated circuit by generating a logic level according to a voltage level that may be applied to an input pin by an external source. Where a differential input pin is provided by an integrated circuit, a situation that is commonly found in high speed serial interface circuits, two voltage levels may be received by two input pins comprising the integrated circuit. A logic level representing a bit in the serial input stream may the be generated according to the difference of the two input voltage levels.

In one alternative method of the present invention, the plurality of logic levels emanating from the serial-to-parallel converter may be directed to the test access port based on the state of a monitor signal. According to this illustrative method, a logic level may be received from a preceding monitoring cell and a logic level may be received from the serial-to-parallel converter. Where the monitor signal is inactive, the logic level received from the preceding monitoring cell may be forwarded to a succeeding monitoring cell whereas the logic level received from the serial-to-parallel converter is so directed if the monitor signal is active.

The present invention further comprises an integrated circuit that typically comprises a functional circuit element that sources a plurality of logic signals. According to this illustrative example embodiment of an integrated circuit, a test access port comprising the invention is provided and is also capable of sourcing a plurality of logic signals. According to one illustrative embodiment of the invention, a serializer may further comprise the invention and may receive either the plurality of logic signals sourced by the functional circuit element or from the test access port. A substitution signal may be used to direct the serializer to select one or the other of these sources for logic signals.

According to this example embodiment, an integrated circuit may further comprise an output pin that receives the serial output of the serializer and directs a voltage level outward from the integrated circuit where the voltage level represents the logic level of a bit emanating from the shift register. According to one alternative embodiment of an integrated circuit of the present invention, two output pins may comprise the integrated circuit. In this case, a first output pin may convey a first voltage level and a second output pin may convey a second voltage level. These voltage levels are typically used to convey a differential voltage according to the logic level representing a bit emanating from the shift register.

An integrated circuit according to the present invention may also comprise an input pin capable of receiving serial data. A serial-to-parallel converter typically receives serial data forwarded by the input pin and generates a plurality of parallel logic signals. These may then be directed to a functional circuit element. The integrated circuit may further comprise the functional circuit element.

The integrated circuit of the present invention further comprises a boundary scan cell that is capable of monitoring the state of one of the plurality of logic signals generated by the serial-to-parallel converter. In one illustrative embodiment of the present invention, a boundary scan cell typically comprises a monitor input, a daisy-chain input, a logic input and a daisy-chain output. Accordingly, the boundary scan cell typically forwards to its daisy-chain output the logic value present at its daisy-chain input when the monitor input is inactive. If the monitor input is active, the boundary scan cell forwards to its daisy-chain output the logic value present at its logic input.

According to one alternative embodiment of the present invention, the integrated circuit may comprise an input pin that converts voltage levels present at the input pin to a logic states. In yet another alternative embodiment of the present invention, two input pens may be used to receive two voltage levels representing a differential signal. The two input pins may then convert the differential signal into a logic state.

### BRIEF DESCRIPTION OF THE DRAWINGS

These and other features and advantages of the invention will be more readily apparent upon reading the following description of a preferred exemplified embodiment of the invention and upon reference to the accompanying drawings wherein:

FIG. 1 is a flow diagram that depicts one example method for driving an output pin with a serial data pattern according to the present invention;

FIG. 2 is a flow diagram that depicts one example method for monitoring a high-speed serial input through a test access port according to the present invention;

FIG. 3 is a block diagram of an integrated circuit comprising one illustrative mechanism for driving an output pin with a serial bit stream according to a test pattern received from a test access port according to the present invention; and

FIG. 4 is a block diagram of one illustrative embodiment of an integrated circuit comprising a serial input pin that may be monitored by way of a test access port according to the present invention.

### DETAILED DESCRIPTION OF THE INVENTION

The present invention comprises a method for driving an output pin of an integrated circuit with a serial bit stream. Output pins comprising an integrated circuit that are driven according to the method of the present invention are able to support board level testing wherein the serial output may be directed to a particular test pattern directed to the integrated circuit through a test access port. Accordingly, the serial output, when driven according to the method of the present invention, may be operated at substantially full speed with the test pattern. The present invention further comprises an integrated circuit that implements the methods of the present invention. An integrated circuit according to the present invention may accept a particular test pattern through a test access port and drive a serial bit stream outward from an output pin at substantially full operating speed according to the test pattern.

An integrated circuit according to the present invention may receive data from a test access port and direct these to output pins by way of boundary scan cells. Likewise, boundary scan cells may be used to capture the state of input pins and then direct the captured state to the test access port. Boundary scan architectures are generally taught by IEEE Std 1149.1-2001 entitled “IEEE Standard Test Access Port and Boundary-Scan Architecture” which is incorporated in its entirety herein by reference.

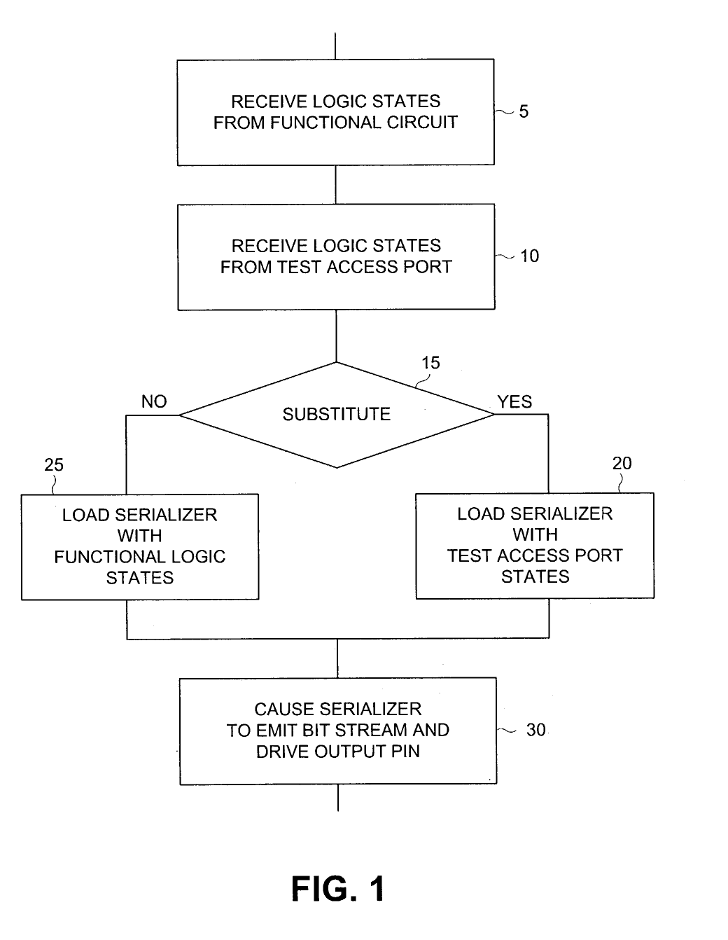

FIG. 1 is a flow diagram that depicts one example method for driving an output pin with a serial data pattern according to the present invention. According to one illustrative method of the present invention, an output pin of an integrated circuit may be driven with a serial bit stream by first receiving a plurality of logic states from a functional circuit element (step 5) comprising the integrated circuit. In many instances, the functional circuit may be a network interface controller. The network interface controller may comprise physical and/or media attachment control. The network interface controller may further comprise data fragmentation circuitry suitable for creating packets of data received from a host interface that may further comprise the integrated circuit.

One example method may further comprise the step of receiving a plurality of logic states from a test access port (step 10). In most circumstances, the plurality of logic states will only be received from the test access port if the test access port is active. According to one variation of this method, the test access port may be compatible with IEEE 1149.1 boundary scan definitions. Generally, the method of the present invention provides for receiving a substitution signal (step 15). The substitution signal typically indicates whether data from the functional circuit element is substituted with data from the test access port. When the substitution signal is active, the method of the present invention provides that the plurality of logic states received from the test access port should be serialized, e.g. by directing the logic states to a serializer (step 20). When the substitution signal is inactive, the method of the present invention provides that the plurality of logic states received from the functional circuit should be serialized, e.g. by directing these logic states to a serializer (step 25) comprising an integrated circuit. According to this illustrative method of the present invention, the serializer may then be clocked in order to emit a bit-stream that may be used to drive an output pin (step 30) comprising the integrated circuit. The serializer may be a shift register.

According to one variation of the illustrative method taught here, receiving a plurality of logic states from a test access port may be accomplished by first receiving a logic level at a first single-bit storage element. Typically, this logic level is received from a preceding single-bit storage element in a serial test access port mechanism comprising a plurality of boundary scan cells as taught in IEEE 1149.1. Accordingly, the logic level is stored in the first single-bit storage element according to a control clock. The stored logic level may then be directed to a second single-bit storage element. Typically, the second single-bit storage element comprises a subsequent boundary scan cell as taught in IEEE 1149.1.

One variation of the illustrative method taught here provides that the output pin of the integrated circuit may be driven by presenting a first voltage level to a first output pin according to a logic level corresponding to a bit in the bit stream generated by the shift register. The method may further comprise a step for presenting a second voltage level representative of the inverse of this logic level to a second output pin.

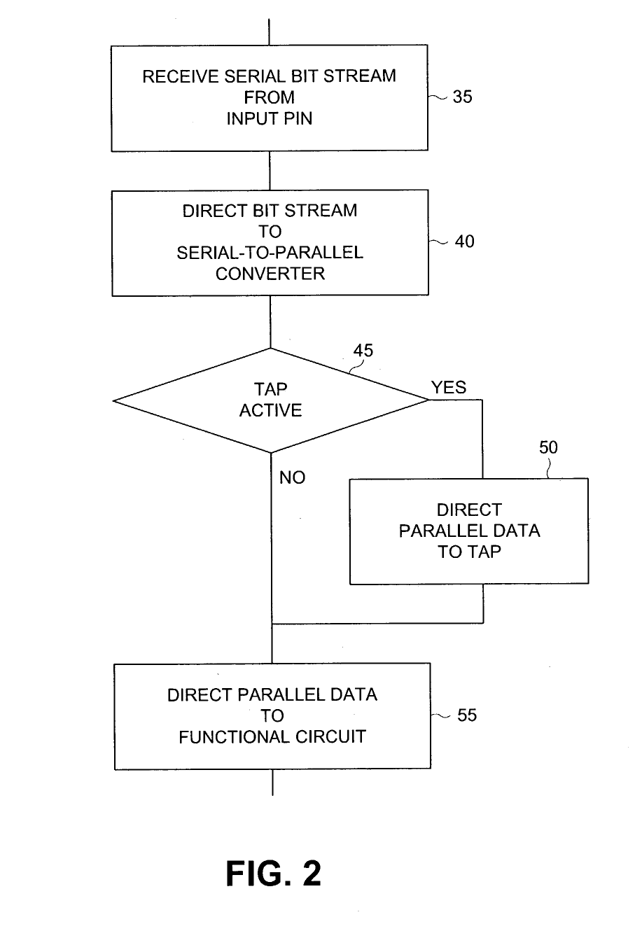

FIG. 2 is a flow diagram that depicts one example method for monitoring a high-speed serial input through a test access port according to the present invention. The present invention also comprises a method for monitoring an input pin comprising an integrated circuit wherein the input pin is capable of receiving a serial bit stream. According to one illustrative method of the present invention, an input pin may be monitored by first receiving a serial bit stream at the input pin (step 35) comprising the integrated circuit. The serial bit stream may then be directed to a serial-to-parallel converter (step 40). Typically, the serial-to-parallel converter will receive the bit stream from the input pin and generate a plurality of logic states that correspond to the bits in the bit stream received by the serial-to-parallel converter. In most variations of this method, the output of the serial-to-parallel converter may be directed to a test access port if the test access port is active (steps 45 and 50). Typically, the test access port is compliant with the teachings of IEEE 1149.1. The plurality of logic states corresponding to the bits in the bit stream may also be directed to a functional circuit element comprising an integrated circuit (step 55).

Receiving a bit stream from the input port, according to one example variation of this method, may comprise generation of a logic level according to the voltage applied to the input pin. The method of the present invention may be altered in order to receive differential signals wherein the step of receiving a serial bit stream at an input pin may comprise receiving a first voltage level at a first input pin, receiving a second voltage level at a second input pin and generating a logic level according to the difference between the first and second voltage levels.

The output of the serial-to-parallel converter may be conveyed to a test access port by first receiving a monitor signal. The monitor signal typically causes the state of one of the plurality of logic states received from the serial-to-parallel converter to be directed to a succeeding monitoring cell. When the monitor signal is not active, a logic level may be received from a preceding monitoring cell and directed to the succeeding monitoring cell.

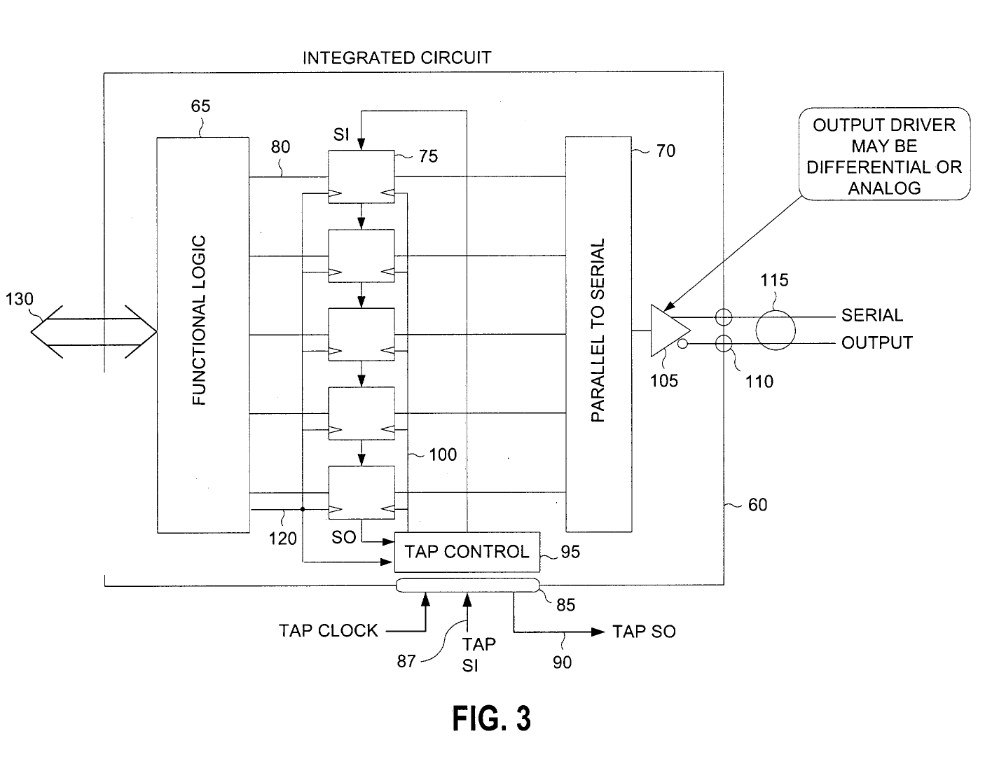

FIG. 3 is a block diagram of an integrated circuit comprising one illustrative mechanism for driving an output pin with a serial bit stream according to a test pattern received from a test access port according to the present invention. Generally, an integrated circuit 60 comprises a functional logic element 65 that may be used to drive a serializer (e.g. a parallel-to-serial converter) 70. According to the teachings of the present invention, the invention comprises boundary scan cells 75 may be introduced in the signal path carrying a plurality of parallel data bits 80 from the functional logic element 65 to the serializer 70. In one illustrative embodiment of an integrated circuit 60 according to the teachings of the present invention, a test access port 85 may be used to convey a test pattern to the input of the serializer 70. Typically, the test access port may be compliant with IEEE 1149.1 but the invention is not intended to be limited to any one type of test access port.

The test access port 85 may receive a test pattern through a serial input 87 (e.g. TAP SI). The serial input may be propagated within the integrated circuit to the boundary scan cells 75 by means of a daisy chain. Accordingly, a boundary scan cell 75 may have a serial input that is driven either by a test access port (TAP) controller 95, that may further comprise the integrated circuit, or by a preceding boundary scan cell. A boundary scan cell may also have a serial output that it may be directed either to a succeeding boundary scan cell or to the test access port controller 95.

When the test access port controller 95 receives the daisy chain signal, it may direct it to a serial output 90 that may be directed to another integrated circuit in accordance with the teachings of IEEE 1149.1. It should be noted that the present invention is not intended to be limited in application to any particular type of test access port. Generally, a boundary scan cell 75 will store a particular bit from a test pattern received by the test access port controller 95 by way of the test access port 85. Storage of a particular bit may be accomplished by receiving a clocking signal 100 from the test access port controller 95 as the test pattern is propagated by the daisy chain from one boundary scan cell to the next.

In one illustrative embodiment of an integrated circuit constructed in accordance with the teachings of the present invention, the serializer 70 may receive parallel data from the boundary scan cells 75. The boundary scan cells 75 may be commanded by the test access port controller 95 to direct parallel data 80 from the functional logic element 65 comprising the integrated circuit. Alternatively, the boundary scan cells 75 may be commanded by the test access port controller 95 to direct the test pattern received by way of the daisy chain to the serializer70.

The serializer70 typically creates a bit stream from the parallel data it receives from the boundary scan cells 75. Accordingly, the bit stream may be directed to an output driver 105 which may further comprise an integrated circuit of the present invention. The output driver 105 may be a single ended driver or it may be a differential driver and is typically used to drive one or more output pins 110 of an integrated circuit. The output of the driver 115 may be digital logic levels or it may be an analog signal.

According to the present invention, boundary scan cells that may be used to drive a serial output in substantially real-time may require a sampling signal 100 in order to ensure that data in the functional logic element 65 is properly captured and propagated to the serializer70. The sampling signal 100 may be any signal that is generated by the test access port 185. Such a sampling signal 100 may first need to be synchronized in phase with an operational clock 120. The operation clock 120 is that clock that governs synchronous logic comprising the functional logic element 65. Such synchronization may be accomplished by a phase-lock-loop that may further comprise the test access port controller 95.

According to one embodiment of the present invention, the functional logic element 65 may be a network interface circuit. The network interface circuit may comprise a physical and/or media attachment controller. The network interface circuit may receive data by way of a host interface 130 that may further comprise an integrated circuit according to the present invention. This data may then be directed from the functional logic element 65 to the boundary scan cells 75.

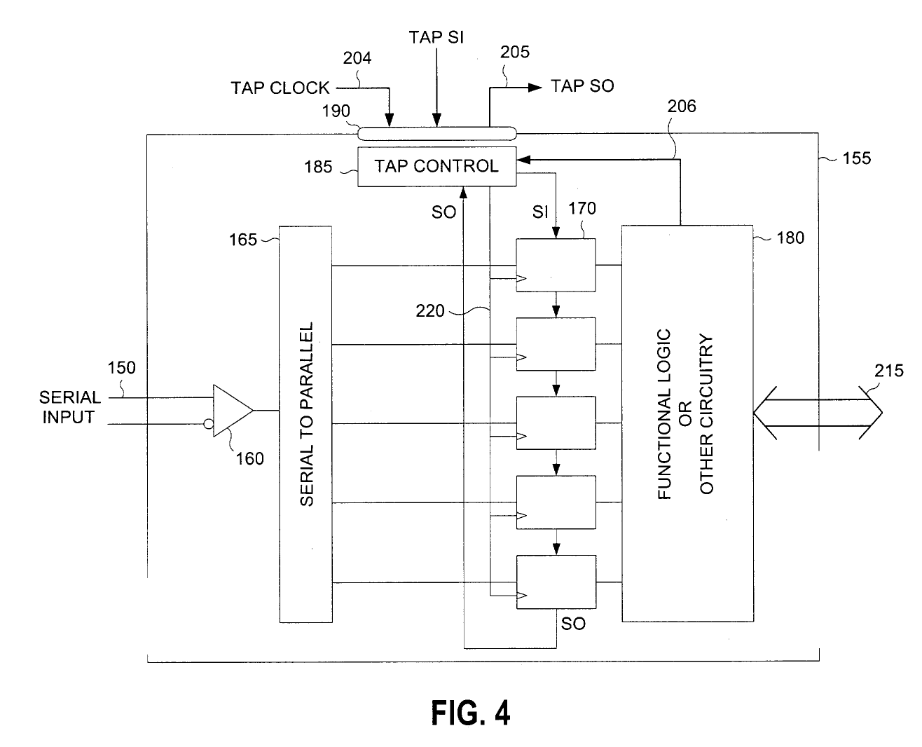

FIG. 4 is a block diagram of one illustrative embodiment of an integrated circuit comprising a serial input pin that may be monitored by way of a test access port according to the present invention. An integrated circuit according to the present invention may comprise a first input pin. An integrated circuit according to the present invention may further comprise a second input pin. According to this embodiment, an input pin may accept a serial bit stream 150. The integrated circuit 155 may further comprise an input receiver 160; the output of which may be directed to a serial-to-parallel converter 165 that also comprises the integrated circuit. The input receiver 160 may be a single ended receiver that may generate a logic level output according to the voltage presented at the first input pin. The input receiver 160 may also comprise a differential receiver that may generate a logic level output according to the difference between a first voltage applied to the first input pin and the second voltage applied to a second input pin.

According to this example embodiment of the invention, the integrated circuit 155 further comprises a plurality of boundary scan cells 170 that are disposed between the parallel data output 175 of the serial-to-parallel converter 165 and a functional logic element 180 that also comprises the integrated circuit. The boundary scan cells 170 are typically connected to each other by means of a daisy chain. The integrated circuit 155 also typically comprises a test access port controller 185 and a test access port 190. In one embodiment of the present invention, the test access port 190 may be compliant with the IEEE 1149.1 standard introduced above, but the invention is not to be limited in scope to this one example of a test access port structure. The test access port 190 comprises a serial input signal that is accepted by the test access port controller 185. This serial input signal is typically routed to a daisy chain that connects a plurality of boundary scan cells 170 to each other.

A first boundary scan cell 170 may receive a serial input signal from the test access port controller 185. The logic state present at the serial input of the first boundary scan cell 170 may be propagated to a succeeding boundary scan cell in the daisy chain. Likewise, the first boundary scan cell may propagate the logic state that it receives from the serial-to-parallel converter 165. Generally, each boundary scan cell 170 will receive a monitor signal 200 from the test access port controller 185. When the monitor signal 200 is active for a particular boundary scan cell, that boundary scan cell will propagate the logic level corresponding to one of the parallel data bits emanating from the serial-to-parallel converter 165 to the next boundary scan cell in the daisy chain.

The last boundary scan cell in the daisy chain typically drives a serial output signal back to the test access port controller 185. The test access port controller 185 may then propagate this serial output to a serial output signal 205 comprising the test access port 185. A plurality of integrated circuit devices may be connected in a daisy chained manner using the serial in and serial out signals of their respective test access ports in accordance with the teachings of IEEE 1149.1. Again, this invention may be applied with varied types of test access port definitions and is not intended to be limited in scope to any particular examples introduced here.

In operation, the serial-to-parallel converter 165 receives a serial bit stream and generates a plurality of data bits each of which corresponds to a bit in the bit stream. A data bit corresponding to a bit in the bit stream may be directed to a boundary scan cell 170. In at least one embodiment of the present invention, the boundary scan cell normally forwards the logic state of the data bit to a functional logic element 180 that typically comprises an integrated circuit of the present invention. In yet other embodiments, the boundary scan cells 170 may not actively propagate a signal to the functional logic element 180. Rather, the boundary scan cells 170 may passively monitor a signal that is conveyed directly from the serial-to-parallel converter 165 to the functional logic element 180.

According to one embodiment of the present invention, the functional logic element 180 may be a network interface circuit. The network interface circuit may comprise a physical and/or media attachment controller. The network interface circuit may further comprise a data aggregator that may receive successive parallel data from the serial-to-parallel converter 135 by way of the boundary scan cells 170 and may then generate packets of data therefrom. The network interface circuit may then convey data packets to a host interface 215 that may further comprise an integrated circuit according to the present invention.

In some embodiments of the present invention, the boundary scan cell may require a sampling signal 220 that is used to capture the state of logic signals received from the serial-to-parallel converter 165. The sampling signal 220 may be any control signal that is generated by the test access port controller 185. Typically, the sampling signal 220 is selected to ensure that high-speed data from the serial-to-parallel converter 165 is properly sampled. In some embodiments, the sampling signal 220 may need to be synchronized with an internal function clock 206 that governs the synchronous operation of the functional logic element 180. Hence, the test access port controller 185 may further comprise a phase-lock-loop that may synchronize the sampling signal 220 to the internal clock 206 driving the functional logic element 180.

Alternative Embodiments

While this invention has been described in terms of several preferred embodiments, it is contemplated that alternatives, modifications, permutations, and equivalents thereof will become apparent to those skilled in the art upon a reading of the specification and study of the drawings. It is therefore intended that the true spirit and scope of the present invention include all such alternatives, modifications, permutations, and equivalents.

What is claimed is:

1. A method for driving an output pin of an integrated circuit with a serial bit stream comprising the steps of:
receiving a plurality of logic states from a functional circuit element;
receiving a plurality of logic states from a test access port if the test access port is active;
receiving a substitution signal;
conveying the plurality of logic states received from the functional circuit element to a serializerif the substitution signal is inactive;
conveying the plurality of logic states received from the test access port to the serializerif the substitution signal is active;
emitting a bit stream from the shift register; and
driving the output pin according to the bit stream.

2. The method of claim 1 wherein the step of receiving a plurality of logic states from a test access port comprises the steps of:
receiving a logic level at a first storage element;
receiving a clock signal that causes the logic level to be stored in the first storage element; and
directing the stored logic level a second storage element.

3. The method of claim 1 wherein the step of driving an output pin according to the bit stream comprises the steps of:
receiving a logic level corresponding to a bit in the bit stream; and
presenting a first voltage level representative of the logic level to a first output pin comprising the integrated circuit.

4. The method of claim 3 wherein the step of driving an output according to the bit stream further comprises presenting a second voltage level representative of the inverse of the logic level to a second output pin comprising the integrated circuit.

5. A method for monitoring an input pin of an integrated circuit that is capable of receiving a serial bit stream comprising the steps of:
receiving a serial bit stream at an input pin comprising the integrated circuit;
directing the serial bit stream to a serial-to-parallel converter;
directing a plurality of logic states corresponding to bits in the bit stream from the serial-to-parallel converter to a functional circuit element; and
directing the plurality of logic states received from the serial-to-parallel converter to a test access port if the test access port is active.

6. The method of claim 5 wherein the step of receiving a serial bit stream at an input pin comprises the step of generating a logic level according to the voltage applied to the input pin.

7. The method of claim 5 wherein the step of receiving a serial bit stream at an input pin comprises the steps of:
receiving a first voltage level at a first input pin comprising the integrated circuit;
receiving a second voltage level at a second input pin comprising the integrated circuit; and
generating a logic level according to the difference between said first and second voltage levels.

8. The method of claim 5 wherein the step directing the plurality of logic states received from the serial-to-parallel converter to a test access port comprises the steps of:
receiving a monitor signal;
receiving a logic level from a preceding monitoring cell;
receiving a logic level corresponding to one of the plurality of logic states received from the serial-to-parallel converter;
directing the logic level received from the preceding monitoring cell to a succeeding monitoring cell if the monitor signal is inactive; and
directing the logic level corresponding to one of the plurality of logic states received from the serial-to-parallel converter to a succeeding monitoring cell if the monitor signal is active.

9. An integrated circuit comprising:
functional circuit element that sources a plurality of logic signals;
test access port that is capable of receiving a plurality of logic signals;
serializer capable of receiving a plurality of logic signals either from the functional circuit element or the test access port according to a substitution signal; and
output pin unit that receives a serial bit stream from the serializer.

10. The integrated circuit of claim 9 further comprising a boundary scan cell that stores an input value from either a serial input or a functional logic input and wherein the serializer receives the value stored by the boundary scan cell.

11. [The integrated circuit of claim 9 wherein the output pin unit comprises an output buffer that converts a logic level into a voltage signal and an output pin that receives the voltage level.

12. The integrated circuit of claim 9 wherein the output pin unit comprises an output buffer that converts a logic level into a first voltage signal and a second voltage signal and first and second output pins that receive the first and second voltage levels.

13. An integrated circuit comprising:
input pin unit that receives a serial data stream;
serial-to-parallel converter that receives a serial data stream from the input pin unit;
functional circuit element that receives a plurality of parallel logic signals from the serial-to-parallel converter; and
plurality of boundary scan cells capable of monitoring the state of the plurality of parallel logic signals.

14. The integrated circuit of claim 13 wherein the input pin unit comprises an input pin and an input receiver that converts the voltage level present at the input pin into a logic state.

15. The integrated circuit of claim 13 wherein the input pin unit comprises a first input pin and a second input pin and a differential input receiver that converts the voltage levels present at the first and second input pins into a logic state.

16. The integrated circuit of claim 13 wherein a boundary scan cell comprises:
monitor signal input that receives a monitor signal;
daisy-chain input for receiving a logic signal from a preceding boundary scan cell;
logic input for receiving a logic signal from a serial-to-parallel converter; and
daisy-chain output that reflects the state of the daisy-chain input if the monitor signal is inactive and reflects the state of the logic input if the monitor signal is active.
